(19) United States
(12) Patent Application Publication
(10) Pub. No.: US 2012/0058281 A1
(43) Pub. Date: Mar. 8, 2012

(54) METHODS FOR FORMING LOW MOISTURE DIELECTRIC FILMS

(75) Inventors: Zhong Qiang Hua, Saratoga, CA (US); Lei Luo, San Jose, CA (US); Manuel A. Hernandez, Santa Clara, CA (US); Zhitao Cao, Campbell, CA (US); Kedar Sapre, San Jose, CA (US); Ajay Bhatnagar, Mountain View, CA (US)

(73) Assignee: Applied Materials, Inc., Santa Clara, CA (US)

(21) Appl. No.: 13/041,201

(22) Filed: Mar. 4, 2011

Related U.S. Application Data
(60) Provisional application No. 61/313,206, filed on Mar. 12, 2010.

(51) Int. Cl. B05D 5/00; C23C 16/56; C23C 16/50; C23C 16/40; C23C 16/44

(52) U.S. Cl. 427/569

(57) ABSTRACT

A method for forming a pre-metal dielectric (PMD) layer or an inter-metal dielectric (IMD) layer over a substrate includes placing the substrate in a chemical vapor deposition (CVD) process chamber and forming a first oxide layer over the substrate in the CVD process chamber. The first oxide layer is formed using a thermal CVD process at a temperature of about 450° C. or less and a sub-atmospheric pressure. The method also includes forming a second oxide layer over the first oxide layer in the CVD process chamber. The second oxide layer is formed using a plasma enhanced chemical vapor deposition (PECVD) process at a temperature of about 450° C. or less and a sub-atmospheric pressure. The substrate remains in the CVD process chamber during formation of the first oxide layer and the second oxide layer.

### CROSS-REFERENCES TO RELATED APPLICATIONS

The present invention claims benefit of priority under 35 U.S.C. §119(e) of U.S. Provisional Application No. 61/313,206, filed Mar. 12, 2010, the content of which is incorporated herein by reference in its entirety for all purposes.

### BACKGROUND

The present invention relates generally to semiconductor processing. More particularly, the present invention relates to methods for forming low moisture dielectric films or dielectric films with a low moisture content. Embodiments of the present invention may be used to form low moisture doped or undoped dielectric layers, such as borophosphosilicate glass (BPSG) layers, borosilicate glass (BSG) layers, phosphosilicate glass (PSG) layers, and undoped silicate glass (USG) layers. Such dielectric layers may be used, for example, to form pre-metal dielectric (PMD) layers, inter-metal dielectric (IMD) layers, shallow trench isolation layers, insulating layers, and the like.

One of the primary steps in fabricating modern semiconductor devices is forming a dielectric layer on a semiconductor substrate. As is well known in the art, such a dielectric layer can be deposited by chemical vapor deposition (CVD). In a conventional thermal CVD process, reactive gases are supplied to the substrate surface where heat-induced chemical reactions take place to produce a desired film. In a conventional plasma enhanced CVD (PECVD) process, a controlled plasma is formed to decompose and/or energize reactive species to produce the desired film. In general, reaction rates in thermal CVD and PECVD processes may be controlled using temperature, pressure, and/or reactant gas flow rates.

Increasingly stringent requirements for dielectric films are needed to produce high quality devices. One concern with dielectric films is moisture content or moisture affinity. Many dielectric films have a low moisture content as deposited but quickly absorb moisture after deposition. Affinity for moisture generally increases as deposition temperature of the film decreases. As a consequence, moisture is becoming a more significant consideration with recent trends toward lower thermal budgets. Moisture can change film structure, reduce film stress, and/or increase dielectric constant. Moisture in dielectric films that are used as PMD or IMD layers can cause oxidation of metal and/or barrier layers. This can affect electrical performance and adhesion to the dielectric films.

Thus, there is a need for improved methods of forming dielectric films with low moisture content and/or low moisture affinity. These and other needs are addressed in the present application.

### SUMMARY

Some embodiments of the present invention provide improved methods for forming dielectric films with a low moisture content and/or with a low affinity for moisture. In accordance with an embodiment, for example, a method for forming a PMD layer and a metal layer over a substrate includes placing the substrate in a CVD process chamber and forming a first oxide layer over the substrate in the CVD process chamber. The first oxide layer is formed using a thermal CVD process at a temperature of about 450° C. or less and a sub-atmospheric pressure. The thermal CVD process uses a first process gas comprising ozone and TEOS. The method also includes forming a second oxide layer over the first oxide layer in the CVD process chamber. The second oxide layer is formed using a PECVD process at a temperature of about 450° C. or less and a sub-atmospheric pressure. The PECVD process uses a second process gas comprising oxygen and TEOS. The substrate remains in the CVD process chamber during formation of the first oxide layer and the second oxide layer. The method also includes removing the substrate from the CVD process chamber, forming a barrier layer over the second oxide layer in a barrier deposition chamber, and forming the metal layer over the barrier layer in a metal deposition chamber.

In accordance with another embodiment, a method for forming a PMD layer over a substrate includes placing the substrate in a CVD process chamber and forming a first oxide layer over the substrate in the CVD process chamber. The first oxide layer is formed using a thermal CVD process at a temperature of about 450° C. or less and a sub-atmospheric pressure. The method also includes forming a second oxide layer over the first oxide layer in the CVD process chamber. The second oxide layer is formed using a PECVD process at a temperature of about 450° C. or less and a sub-atmospheric pressure. The substrate remains in the CVD process chamber during formation of the first oxide layer and the second oxide layer. The method also includes removing the substrate from the CVD process chamber and exposing the substrate to a degas process in a degas chamber. The degas process is at a temperature of about 400° C. or more and a pressure of about 12 Torr or less.

In accordance with yet another embodiment, a method for forming a PMD layer and a metal layer over a substrate includes placing the substrate in a CVD process chamber and forming a first oxide layer over the substrate in the CVD process chamber. The first oxide layer is formed using a thermal CVD process at a temperature of about 450° C. or less and a sub-atmospheric pressure. The method also includes forming a second oxide layer over the first oxide layer in the CVD process chamber. The second oxide layer is formed using a PECVD process at a temperature of about 450° C. or less and a sub-atmospheric pressure. The substrate remains in the CVD process chamber during formation of the first oxide layer and the second oxide layer. The method also includes removing the substrate from the CVD process chamber and exposing the substrate to a degas process in a degas chamber. The degas process is at a temperature of about 400° C. or more and a pressure of about 12 Torr or less. The method also includes forming a barrier layer over the second dielectric layer in a barrier deposition chamber and forming the metal layer over the barrier layer in a metal deposition chamber.

Numerous benefits are achieved using embodiments of the present invention over conventional techniques. For example, some embodiments can be used to form dielectric layers that have a low moisture content. Other embodiments can be used to form dielectric layers that have a low affinity for moisture. These embodiments can be used, for example, to provide PMD and IMD layers with a low moisture content that can reduce or eliminate oxidation in metal layers. This can improve device electrical performance and adhesion to the dielectric layers. Depending upon the embodiment, one or more of these benefits may exist. These and other benefits are described throughout the specification and more particularly below.

### BRIEF DESCRIPTION OF THE DRAWINGS

FIGS. 1A-1B are cross-sectional views of an exemplary chemical vapor deposition apparatus that may be used to form low moisture dielectric layers in accordance with an embodiment of the invention;

FIG. 2 is a plot of stress versus time for thermal CVD oxide layers formed with and without a PECVD oxide layer in accordance with an embodiment of the invention;

FIG. 3 is a plot of FTIR absorbance versus wavelength for thermal CVD oxide layers formed with and without PECVD oxide layers in accordance with an embodiment of the invention;

FIG. 4 is a plot of H₂O partial pressure versus time for thermal CVD oxide layers formed with and without PECVD oxide layers in accordance with an embodiment of the invention; and

FIG. 5 is a simplified flow chart illustrating an exemplary method for forming a low moisture dielectric layer over a substrate in accordance with an embodiment of the invention.

### DETAILED DESCRIPTION

The present invention provides methods for forming PMD layers with low moisture content and/or low moisture affinity. As used herein, PMD layers include dielectric layers formed after a first metal deposition such as IMD layers. One embodiment of the invention includes forming a thermal CVD oxide and an overlying PECVD oxide in the same chamber. The thermal CVD oxide has a low moisture content as deposited but a high affinity for moisture. By depositing both layers in the same chamber, the as-deposited low moisture condition of the thermal CVD layer is maintained by sealing the layer with the PECVD oxide. The PECVD oxide essentially prevents moisture from diffusing into the thermal CVD oxide. The PECVD oxide has a much lower affinity for moisture than the thermal CVD oxide, and any moisture that diffuses into the PECVD oxide can be reduced by exposing the layers to a degas process. The degas process may include inert gas exposure at an elevated temperature and reduced pressure. Low moisture dielectric layers formed in accordance with embodiments of the invention can reduce oxidation and improve adhesion of barrier and metal layers. This can improve device performance.

### Exemplary Process Chamber

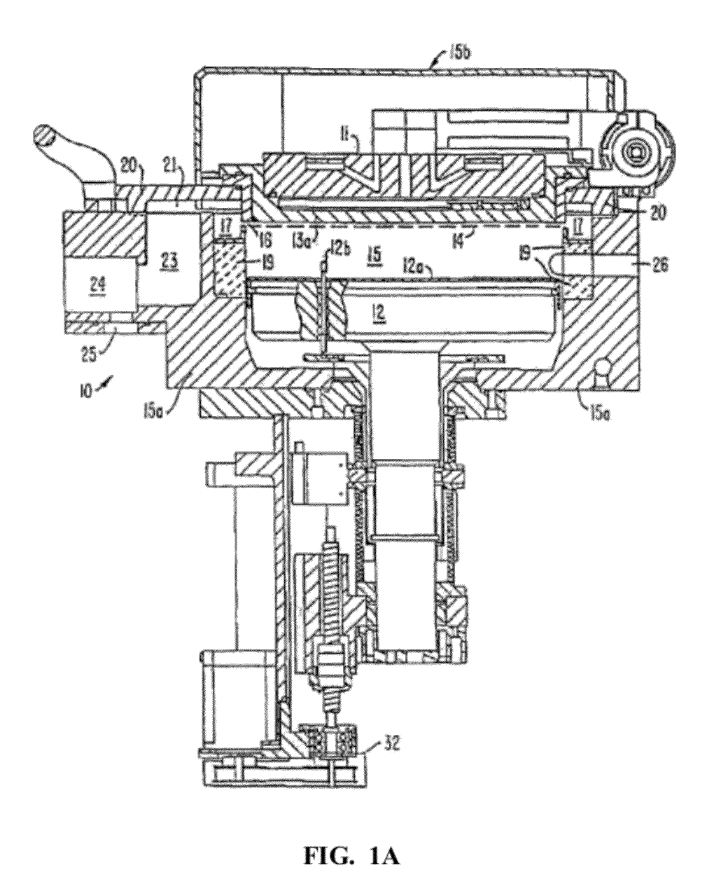

FIGS. 1A-1B are cross-sectional views of an exemplary CVD apparatus that may be used to form oxide layers along sidewalls of vias using thermal CVD processes. FIG. 1A shows a cross-sectional view of a CVD system 10 having a processing chamber 15 that includes a chamber wall 15a and chamber lid assembly 15b. CVD system 10 contains a gas distribution manifold 11 for dispersing process gases to a substrate (not shown) that rests on a heated pedestal or substrate support 12 centered within the process chamber. During processing, the substrate (e.g. a semiconductor wafer) is positioned on a surface 12a of pedestal 12. The pedestal can be moved controllably between a lower loading position (depicted in FIG. 1A) and an upper processing position (indicated by dashed line 14 in FIG. 1A and shown in FIG. 1B).

Deposition and carrier gases are introduced into chamber 15 through perforated holes of a gas distribution member or faceplate. More specifically, deposition process gases flow into the chamber through the inlet manifold 11 (indicated by arrow 40 in FIG. 1B), through a conventional perforated blocker plate 42, and through holes in the gas distribution faceplate.

Before reaching the manifold, deposition and carrier gases are input from gas sources 7 through gas supply lines 8 (FIG. 1B) into a mixing system 9 where they are combined and then sent to manifold 11.

The deposition process performed in CVD system 10 may be a plasma-enhanced process. In a plasma-enhanced process, an RF power supply 44 may apply electrical power between the gas distribution faceplate and the pedestal so as to excite the process gas mixture to form a plasma within the cylindrical region between the faceplate and the pedestal. Constituents of the plasma react to deposit a desired film on the surface of the substrate supported on pedestal 12.

CVD system 10 may also be used for thermal deposition processes. In a thermal process, RF power supply 44 would not be utilized, and the process gas mixture would thermally react to deposit the desired films on the surface of the substrate supported on pedestal 12. The support pedestal 12 may be resistively heated to provide thermal energy for the reaction.

The reactant gases that are not deposited in the chamber, including reaction by-products, are evacuated from the chamber by a vacuum pump (not shown). Specifically, the gases are exhausted through an annular, slot-shaped orifice 16 surrounding the reaction region and into an annular exhaust plenum 17. The annular slot 16 and the plenum 17 are defined by the gap between the top of the chamber's cylindrical side-wall 15a (including the upper dielectric lining 19 on the wall) and the bottom of the circular chamber lid 20. The 360° circular symmetry and uniformity of the slot orifice 16 and the plenum 17 help achieve a uniform flow of process gases over the wafer so as to deposit a uniform film on the wafer.

From the exhaust plenum 17, the gases flow underneath a lateral extension portion 21 of the exhaust plenum 17, through a downward-extending gas passage 23, past a vacuum shut-off valve 24, and into the exhaust outlet 25 that connects to the external vacuum pump (not shown) through a foreline (also not shown).

The pedestal 12 (preferably aluminum, ceramic, or a combination thereof) may be resistively heated. The wiring to the heater element passes through the stem of the pedestal 12. Typically, any or all of the chamber lining, gas inlet manifold faceplate, and various other reactor hardware are made out of material such as aluminum, anodized aluminum, or ceramic.

A lift mechanism and motor 32 (FIG. 1A) raises and lowers the heater pedestal assembly 12 and its wafer lift pins 12b as wafers are transferred into and out of the body of the chamber by a robot blade through an opening 26 in a side of the chamber 15. The motor, valves, flow controllers, gas delivery system, throttle valve, RF power supply, chamber, substrate heating system, and heat exchangers are all controlled by a system controller 34 (FIG. 1B) over control lines 36. Controller 34 relies on feedback from sensors to determine the position of movable mechanical assemblies such as the throttle valve and susceptor which are moved by appropriate motors under the control of controller 34.

In some embodiments, the system controller includes a hard disk drive (memory 38), a floppy disk drive, and a processor 37. The processor may include a single-board computer (SBC), analog and digital input/output boards, interface boards, and stepper motor controller boards.

System controller 34 may control all of the activities of the CVD apparatus. The system controller 34 executes system control software stored as a computer program on a computer-readable medium such as memory 38. Memory 38 may be a hard disk drive or other kind of memory. The computer program includes sets of instructions that dictate the timing, mixture of gases, chamber pressure, chamber temperature, RF power levels, susceptor position, and other parameters of a particular process. Other computer programs stored on other memory devices may also be used to operate controller 34.

The exemplary CVD apparatus shown in FIGS. 1A-1B may be used to form thermal CVD layers and PECVD layers that can be used to form low moisture dielectric films in accordance with some embodiments of the invention. As an example, a thermal CVD oxide layer can be formed using a process gas that includes a silicon precursor (e.g., silane (SiH₄), tetraethylorthosilicate (TEOS), octamethylcyclotetrasiloxane (OMCTS), etc.), an oxygen source (e.g., O₂, ozone, etc.), and optionally an inert gas (e.g., Ar, He, and/or N₂, etc.). In an exemplary embodiment, the thermal CVD process is a sub-atmospheric CVD (SACVD) process using a process gas that comprises TEOS at a flow of about 1.5 gm to about 3.5 gm and ozone at a flow of about 11000 sccm to about 16000 sccm. The process gas may also include N₂ at a flow of about 25000 sccm to about 29000 sccm. The temperature during the thermal CVD process may be in the range of about 350° C. to 450° C. to prevent damage to other layers.

While thermal CVD layers formed using these conditions have a low moisture content as deposited, they quickly absorb moisture when exposed to a moisture-containing ambient. To prevent the thermal CVD layer from absorbing moisture, an overlying PECVD layer can be formed in the same chamber thus preventing exposure of the thermal CVD layer to a moisture-containing ambient. Since the PECVD layer has a lower affinity for moisture, the moisture content of the thermal CVD layer can be reduced compared to thermal CVD layers that do not include overlying PECVD layers.

An overlying PECVD layer in accordance with an embodiment may be formed using a process gas that includes a silicon precursor (e.g., silane (SiH₄), tetraethylorthosilicate (TEOS), octamethylcyclotetrasiloxane (OMCTS), etc.), an oxygen source (e.g., O₂, ozone, etc.), and optionally an inert gas (e.g., Ar, He, and/or N₂, etc.). In an exemplary embodiment, the PECVD process uses a process gas that comprise TEOS at a flow of about 0.5 gm to about 1.5 gm and O₂ at a flow of about 7000 sccm to about 9000 sccm. The process gas may also include He at a flow of about 7000 sccm to about 11000 sccm. The temperature during the PECVD process may be in the range of about 350° C. to 450° C. The temperature may be about the same as that used for the thermal CVD process.

### Experimental Results and Measurements

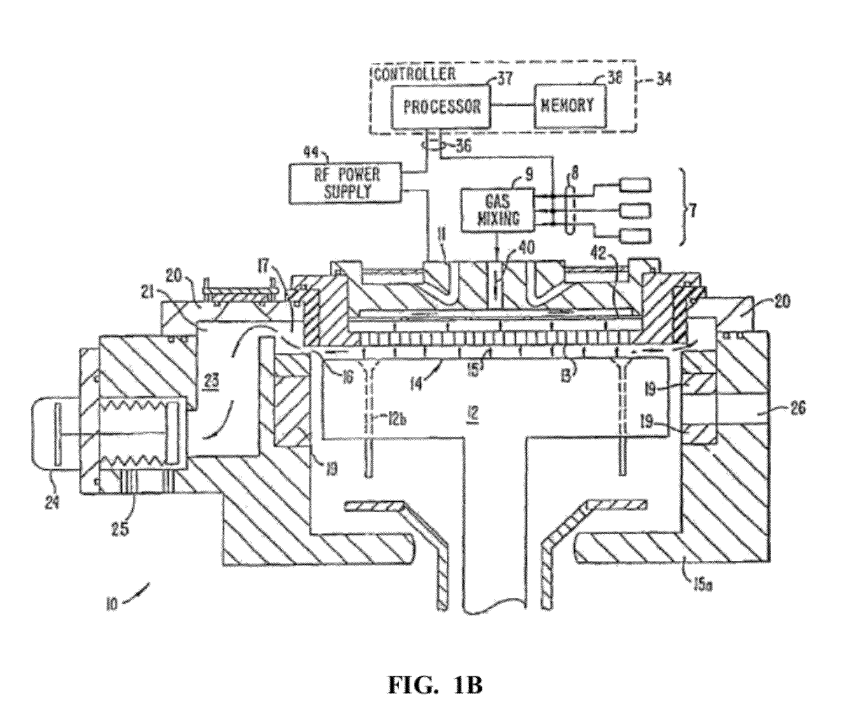

FIG. 2 is a plot of stress versus time for thermal CVD oxide layers formed with and without a PECVD oxide layer in accordance with an embodiment of the invention. In this example, the thermal CVD and PECVD layers were deposited at a temperature of 400° C. This plot shows that stress of the thermal CVD dielectric layer decreases from about 300 MPa after deposition to about 100 MPa after about 1400 minutes. The decrease in stress is a result of moisture absorption. This plot also shows that stress of the thermal CVD dielectric layer formed with an overlying PECVD dielectric layer remains relatively stable during the same time period. This suggests that the PECVD layer blocks diffusion of moisture into the thermal CVD layer.

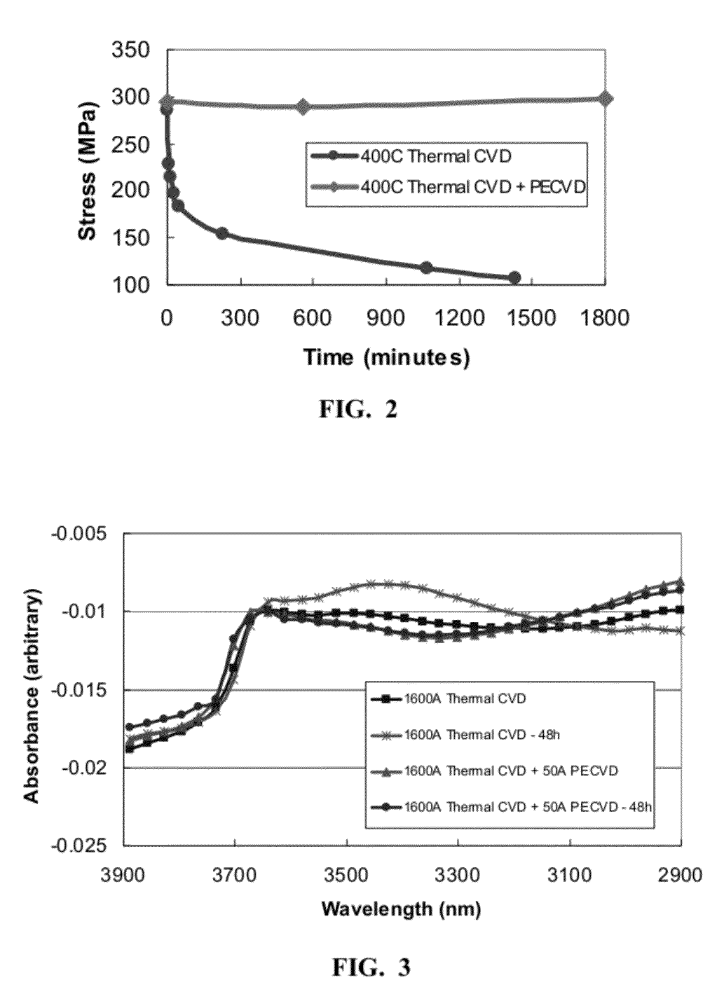

FIG. 3 is a plot of FTIR absorbance versus wavelength for thermal CVD oxide layers formed with and without PECVD oxide layers in accordance with an embodiment of the invention. This plot shows that thermal CVD layers that do not include an overlying PECVD layer have a larger water absorption peak. Further, the water absorption peak is greater for the sample analyzed 48 hours after deposition than for the sample analyzed shortly after deposition. This plot also shows that the water absorption peak is suppressed using a 50 Å PECVD oxide layer over the thermal CVD oxide layer. Using an overlying PECVD layer, there is no increase in water absorption peak between a sample analyzed 48 hours after deposition and a sample analyzed shortly after deposition. This indicates that the PECVD layer not only blocks diffusion of moisture into the thermal CVD layer but also that the PECVD layer has a lower affinity for moisture than the thermal CVD layer.

In accordance with an embodiment, the overlying PECVD layer may be thinner than the thermal CVD layer. For example, while the thermal CVD layer may have a thickness of as much as 10,000 Å or more depending on the particular application, the overlying PECVD layer may have a thickness of as little as 50 Å or less. The thermal CVD layer is more conformal than the PECVD layer when formed over structures having high aspect ratios. In such applications, it is desirable to minimize a thickness of the less conformal PECVD layer. Conformality of the thermal CVD layer can be further improved using a sub-atmospheric pressure during the deposition process. As shown in FIG. 3, PECVD layers having a thickness of 50 Å are sufficient to prevent moisture from diffusing into the thermal CVD layer.

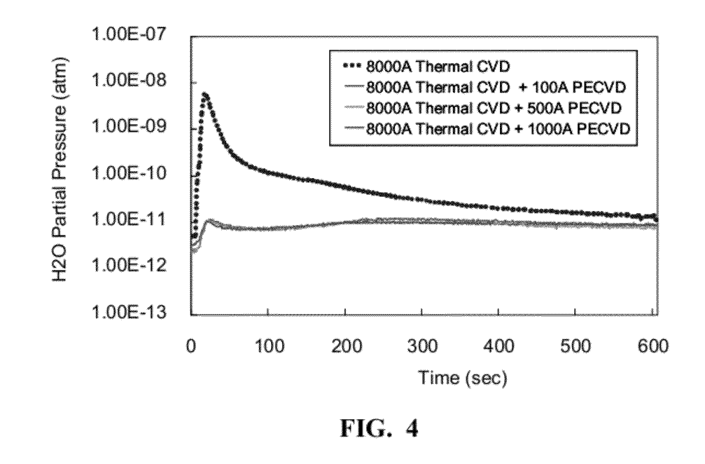

FIG. 4 is a plot of H₂O partial pressure versus time for thermal CVD oxide layers formed with and without PECVD oxide layers in accordance with an embodiment of the invention. This data was collected using a quadropole mass spectrometer attached to a degas chamber. In this example, temperature during the degas process was 400° C., and pressure during the degas process was cycled between 0.5 Torr during a step without inert gas flow and 8 Torr during a step with inert gas flow. This plot shows that H₂O partial pressure decays exponentially with time for a thermal CVD layer that does not include an overlying PECVD layer. For the thermal CVD layer, it takes about 10 minutes for the H₂O partial pressure to reach a range of about 10⁻¹¹ atm. This plot also shows that it takes less than about 1 minute for H₂O partial pressure to reach a similar range for thermal CVD layers having an overlying PECVD layer. Increasing thickness of the overlying PECVD layer from 100 Å to 1000 Å had no impact on degas time. As illustrated by this data, a degas process can be used prior to barrier layer deposition to quickly remove moisture from the thermal CVD/PECVD film.

### Exemplary Methods of Forming a Low Moisture Dielectric Layer

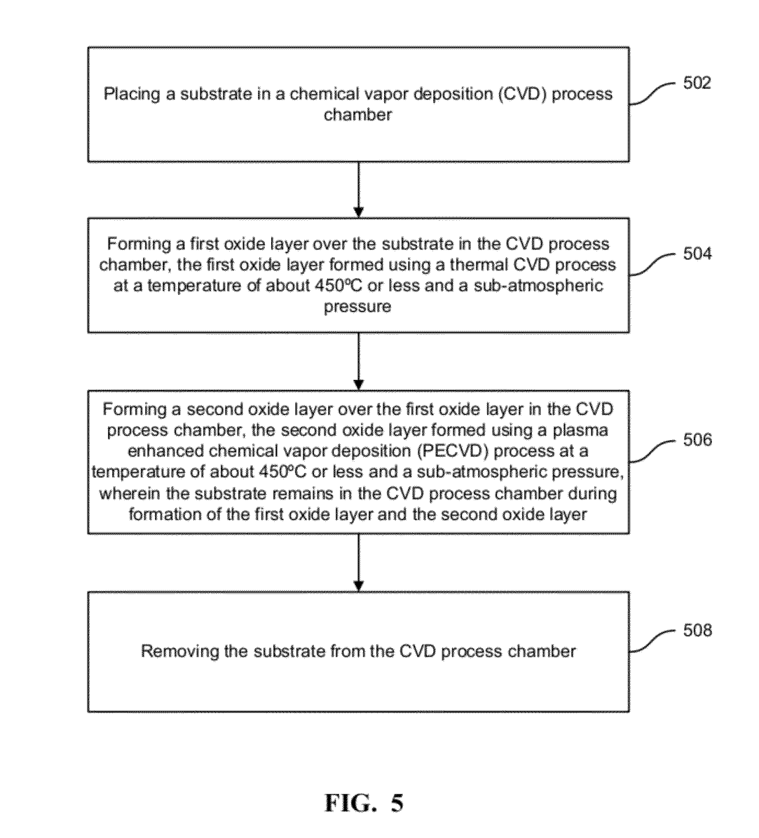

FIG. 5 is a simplified flow chart illustrating an exemplary method for forming a low moisture dielectric layer over a substrate in accordance with an embodiment of the invention. The method includes placing a substrate in a CVD process chamber (502) and forming a first oxide layer over the substrate in the CVD process chamber using a thermal CVD process at a temperature of about 450° C. or less and a sub-atmospheric pressure (504). The method also includes forming a second oxide layer over the first oxide layer in the CVD process chamber using a PECVD process at a temperature of about 450° C. or less and a sub-atmospheric pressure (506). The substrate remains in the CVD process chamber during formation of the first oxide layer and the second oxide layer. The method also includes removing the substrate from the CVD process chamber (508).

In accordance with an embodiment, a method of forming a low moisture dielectric layer may also include exposing the deposited thermal CVD and PECVD layers to a degas process. In an embodiment, the degas process includes exposing the deposited layers to a temperature of about 400° C. or more at a pressure of about 12 Torr or less. The degas process can remove moisture from the deposited thermal CVD and PECVD layers. In some embodiments, the degas process may include one or more cycle purges. Each cycle purge may include a step without inert gas flow at a pressure of between about 0.1 Torr and 1 Torr and a step with inert gas flow (e.g., Ar, He, and/or N₂) at a pressure of between about 4 Torr and 12 Torr. A duration of the entire degas process may be between about 15 seconds to about 120 seconds.

Low dielectric layers formed in accordance with embodiments of the invention may be used as PMD layers. In these applications, a barrier layer may be formed over the PECVD layer in a barrier deposition chamber, and a metal layer may be formed over the barrier layer in a metal deposition chamber. The barrier layer and the metal layer may be formed in accordance with known techniques. The low moisture of the dielectric layer can reduce oxidation of the barrier and/or metal layers. This can improve device performance and adhesion to the dielectric layers.

While the present invention has been described in terms of specific embodiments, it should be apparent to those skilled in the art that the scope of the invention is not limited to the embodiments described herein. For example, it is to be understood that the features of one or more embodiments of this invention may be combined with one or more features of other embodiments of the invention without departing from the scope of the invention. Also, the examples and embodiments described herein are for illustrative purposes only, and various modifications or changes in light thereof will be evident to persons skilled in the art and are to be included within the spirit and purview of this application and the scope of the appended claims.

What is claimed is:

1. A method for forming a pre-metal dielectric (PMD) layer and a metal layer over a substrate, the method comprising:
placing the substrate in a chemical vapor deposition (CVD) process chamber;
forming a first oxide layer over the substrate in the CVD process chamber, the first oxide layer formed using a thermal CVD process at a temperature of about 450° C. or less and a sub-atmospheric pressure, the thermal CVD process using a first process gas comprising ozone and TEOS;
forming a second oxide layer over the first oxide layer in the CVD process chamber, the second oxide layer formed using a plasma enhanced chemical vapor deposition (PECVD) process at a temperature of about 450° C. or less and a sub-atmospheric pressure, the PECVD process using a second process gas comprising oxygen and TEOS, wherein the substrate remains in the CVD process chamber during formation of the first oxide layer and the second oxide layer;
removing the substrate from the CVD process chamber;
forming a barrier layer over the second oxide layer in a barrier deposition chamber; and
forming the metal layer over the barrier layer in a metal deposition chamber.

2. The method of claim 1 wherein the first oxide layer has a thickness of about 1000 Å or more and the second oxide layer has a thickness of about 75 Å or less.

3. The method of claim 1 further comprising:
after removing the substrate from the CVD process chamber and before forming the barrier layer, placing the substrate in a degas chamber;
exposing the substrate to a degas process at a temperature of about 400° C. or more and a pressure of about 12 Torr or less; and
removing the substrate from the degas chamber.

4. The method of claim 3 wherein the degas process comprises one or more cycle purges, wherein each cycle purge includes a step without inert gas flow at a pressure of about 0.5 Torr or less, and a step with inert gas flow at a pressure of about 8 Torr or more.

5. A method for forming a pre-metal dielectric (PMD) layer over a substrate, the method comprising:
placing the substrate in a chemical vapor deposition (CVD) process chamber;
forming a first oxide layer over the substrate in the CVD process chamber, the first oxide layer formed using a thermal CVD process at a temperature of about 450° C. or less and a sub-atmospheric pressure;
forming a second oxide layer over the first oxide layer in the CVD process chamber, the second oxide layer formed using a plasma enhanced chemical vapor deposition (PECVD) process at a temperature of about 450° C. or less and a sub-atmospheric pressure, wherein the substrate remains in the CVD process chamber during formation of the first oxide layer and the second oxide layer;
thereafter, removing the substrate from the CVD process chamber; and
exposing the substrate to a degas process in a degas chamber, the degas process at a temperature of about 400° C. or more and a pressure of about 12 Torr or less.

6. The method of claim 5 wherein the first oxide layer has a thickness of about 1000 Å or more and the second oxide layer has a thickness of about 75 Å or less.

7. The method of claim 5 wherein the degas process comprises one or more cycle purges, wherein each cycle purge includes a step without inert gas flow at a pressure of about 0.5 Torr or less, and a step with inert gas flow at a pressure of about 8 Torr or more.

8. The method of claim 5 wherein the thermal CVD process uses a first process gas comprising ozone and TEOS.

9. The method of claim 5 wherein the PECVD process uses a second process gas comprising oxygen and TEOS.

10. A method for forming a pre-metal dielectric (PMD) layer and a metal layer over a substrate, the method comprising:
placing the substrate in a chemical vapor deposition (CVD) process chamber;
forming a first oxide layer over the substrate in the CVD process chamber, the first oxide layer formed using a thermal CVD process at a temperature of about 450° C. or less and a sub-atmospheric pressure;
forming a second oxide layer over the first oxide layer in the CVD process chamber, the second oxide layer formed using a plasma enhanced chemical vapor deposition (PECVD) process at a temperature of about 450° C. or less and a sub-atmospheric pressure, wherein the substrate remains in the CVD process chamber during formation of the first oxide layer and the second oxide layer;
thereafter, removing the substrate from the CVD process chamber;
exposing the substrate to a degas process in a degas chamber, the degas process at a temperature of about 400° C. or more and a pressure of about 12 Torr or less;
thereafter, forming a barrier layer over the second dielectric layer in a barrier deposition chamber; and
thereafter, forming the metal layer over the barrier layer in a metal deposition chamber.

11. The method of claim 10 wherein the first oxide layer has a thickness of about 1000 Å or more and the second oxide layer has a thickness of about 75 Å or less.

12. The method of claim 10 wherein the degas process comprises one or more cycle purges, wherein each cycle purge includes a step without inert gas flow at a pressure of about 0.5 Torr or less, and a step with inert gas flow at a pressure of about 8 Torr or more.

13. The method of claim 10 the thermal CVD process uses a first process gas comprising ozone and TEOS.

14. The method of claim 10 wherein the PECVD process uses a second process gas comprising oxygen and TEOS.
